(19) United States
(12) Patent Application Publication
(10) Pub. No.: US 2025/0140684 A1
(43) Pub. Date: May 1, 2025

(54) DELAMINATION DETECTION STRUCTURE

(71) Applicant: Taiwan Semiconductor Manufacturing Company, Ltd., Hsinchu (TW)

(72) Inventors: Chi-Hui Lai, Taichung City (TW); Yang-Che Chen, Hsin-Chu City (TW); Hsiang-Tai Lu, Hsinchu County (TW); Wei-Ray Lin, Hsinchu City (TW); Tse-Wei Liao, Hsinchu City (TW); Ming Jun Li, New Taipei City (TW)

(21) Appl. No.: 18/440,671

(22) Filed: Feb. 13, 2024

Related U.S. Application Data
(60) Provisional application No. 63/594,574, filed on Oct. 31, 2023.

(51) Int. Cl. H01L 23/522; H01L 21/66; H01L 23/00; H01L 23/48; H01L 23/58

(52) U.S. Cl. CPC H01L 23/5226; H01L 22/32; H01L 23/481; H01L 23/585; H01L 24/08; H01L 24/80; H01L 2224/08145; H01L 2224/80895; H01L 2224/80896

(57) ABSTRACT

A semiconductor includes a first substrate having a device region and a ring region surrounding the device region, a first interconnect structure over the first substrate, the first interconnect structure including a first via tower and a second via tower, a first bonding layer over the first interconnect structure and including a first metal bonding feature, a second bonding layer over the first bonding layer and including a second metal bonding feature in contact with the first metal bonding feature, and a second interconnect structure over the second bonding layer and including a third via tower extending through the second interconnect structure and disposed directly over the ring region. The first via tower is electrically coupled to the second via tower by a first metal line. The first via tower is electrically coupled to the third via tower by the first metal bonding feature and the second metal bonding feature.

### PRIORITY DATA

This application claims priority to U.S. Provisional Patent Application Ser. No. 63/594,574, filed Oct. 31, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line)) that can be created using a fabrication process) has decreased. This sealing down process generally provides benefits by increasing production efficiency and lowering associated costs. Such sealing down has also increased the complexity of processing and manufacturing ICs.

Modern-day IC packaging may involve stacking multiple dies vertically. Hybrid bonding is one of the ways to bond a top die to a bottom die. Like other semiconductor processes, hybrid bonding may fail under stress. Non-bonding or delamination may initiate at corners and edges and propagate to other bonding areas. Early detection of non-bonding is desirable in order to reduce cost and improve yield.

### BRIEF DESCRIPTION OF THE DRAWINGS

The present disclosure is best understood from the following detailed description when read with the accompanying figures. It is emphasized that, in accordance with the standard practice in the industry, various features are not drawn to seale and are used for illustration purposes only. In fact, the dimensions of the various features may be arbitrarily increased or reduced for clarity of discussion.

FIG. 1 illustrates a top view of an integrated circuit (IC) chip package with first-type crack sensors, according to one or more aspects of the present disclosure.

FIG. 2 illustrates a cross-sectional view of the IC device package in FIG. 1 along line A-A′, according to one or more aspects of the present disclosure.

FIG. 3 illustrates a fragmentary cross-sectional view of a first-type crack sensor in a seal ring region of the IC device package in FIG. 1, according to one or more aspects of the present disclosure.

FIG. 4 illustrates an enlarged fragmentary top view of an edge portion of the IC device package in FIG. 1, according to one or more aspects of the present disclosure.

FIG. 5 illustrates an enlarged fragmentary top view of a corner portion of the IC device package in FIG. 1, according to one or more aspects of the present disclosure.

FIG. 6 is a flowchart of a method 300 for forming a crack sensor in a seal ring region of an IC device package, according to one or more aspects of the present disclosure.

FIGS. 7-12 are fragmentary cross-sectional view of a workpiece at various stage of fabrication according to the method in FIG. 6, according to one or more aspects of the present

FIG. 13 illustrates a top view of an integrated circuit (IC) chip package with second-type crack sensors, according to one or more aspects of the present disclosure.

FIG. 14 illustrates a fragmentary cross-sectional view of a second-type crack sensor in a seal ring region of the IC device package in FIG. 13, according to one or more aspects of the present disclosure.

FIG. 15 illustrates an enlarged fragmentary top view of an edge portion of the IC device package in FIG. 13, according to one or more aspects of the present disclosure.

FIG. 16 illustrates an enlarged fragmentary top view of a corner portion of the IC device package in FIG. 13, according to one or more aspects of the present disclosure.

FIG. 17 illustrates crack sensors in seal ring structures of an IC chip in a chip-level testing environment, according to various aspects of the present disclosure.

FIG. 18 illustrates crack sensors in seal ring structures of an IC chip in a package-level testing environment, according to various aspects of the present disclosure.

FIG. 19 illustrates crack sensors in seal ring structures of an IC chip in a system-level testing environment, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed. For avoidance of doubts, the X, Y and Z directions in figures of the present disclosure are perpendicular to one another. Throughout the present disclosure, like reference numerals denote like features, unless otherwise excepted.

Seal structures are used to prevent semiconductor devices in an integrated circuit (IC) chip from being damaged due to mist ingress or stress during singulation of the IC chip. The seal structures may be disposed in a seal ring region that surrounds or goes completely around a device region. Generally, an IC chip includes active devices formed on a semiconductor substrate and an interconnect structure to functionally interconnect the active devices. An IC chip may also be referred to as an IC die or simply, a die. In some packaging scheme, a first die is bonded to a second die by direct bonding. In an example process, a first bonding layer is formed over an interconnect structure of the first die and a second bonding layer is formed over an interconnect structure of the second die. The first die and the second die are then bonded together to form an IC device package by bonding the first bonding layer to the second bonding layer. It has been observed that an initial non-bond or delamination between the first bonding layer and the second bonding layer tends to begin near an edge or a corner of the IC device package. The initial non-bond or delamination may continue to propagate through IC device package to cause failure or defects. It is desirable to have early detection of the initial non-bond or delamination.

The present disclosure provides crack sensors in a seal ring region of an IC device package to enable early detection of non-bond or delamination. In some examples, crack sensors of the present disclosure have a daisy chain structure that include not only metal features in two interconnect structures but also metal bonding features in the bonding layers. This way, when a non-bond situation or a delamination develops, the crack sensor would have an open circuit, rather than a closed loop. Additionally, because the crack sensors are disposed in the seal ring region that surrounds a device region, they are closer to corners and edge where onset of non-bond or an onset of delamination is likely to take place. When the crack sensors include via towers that span multiple metallization layers in the two interconnect structures, they can also be used to detect early non-bond or delamination among the intermetal dielectric (IMD) layers in the interconnect structures.

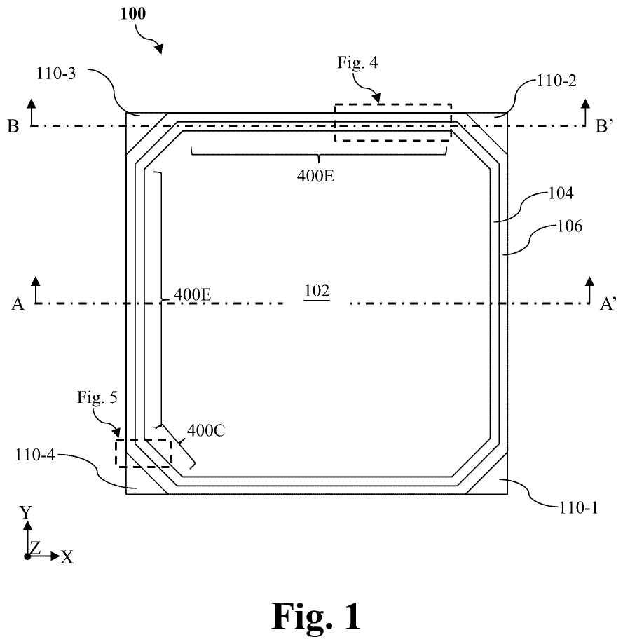

Reference is first made to FIG. 1, which includes a top view of an IC device package 100. The IC device package 100 includes a device region 102, an inner seal ring region 104 continuously surrounding the device region 102, and an outer seal ring region 106 continuously surrounding the inner seal ring region 104. In some embodiments, each of the device region 102, the inner seal ring region 104, and the outer seal ring region 106 includes four cutoff corners to have an octagonal shape from a top view. As illustrated in FIG. 1, four corner areas 110-1, 110-2, 110-3, and 110-4 fill the four cutoff corners such that the IC device package 100 has a square shape or a rectangular shape from a top view. In one embodiment, the IC device package 100 includes a square shape in a top view. In some implementations, each of the four corner areas 110-1, 110-2, 110-3, and 110-4 resembles an isosceles right triangle.

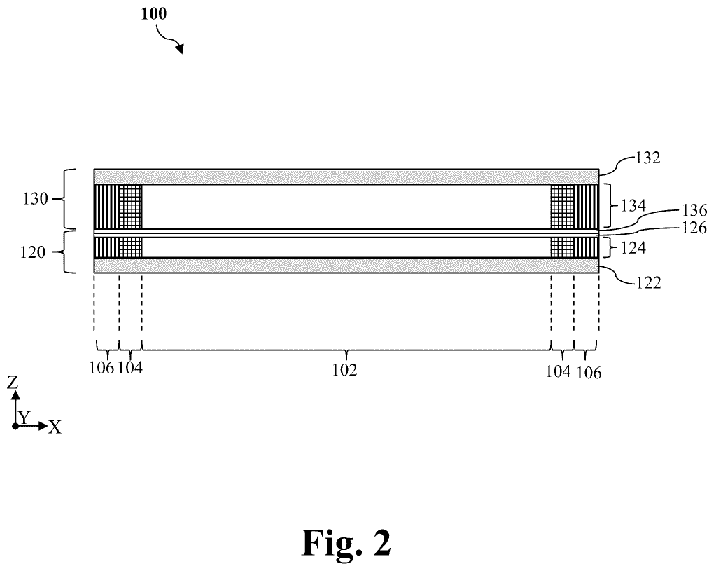

FIG. 2 illustrates a cross-sectional view of the IC device package 100 in FIG. 1 along line A-A′. The IC device package 100 includes a bottom die 120 and a top die 130. The bottom die 120 includes a bottom substrate 122, a bottom interconnect structure 124 disposed over the bottom substrate 122, and a bottom bonding layer 126 disposed on the bottom interconnect structure 124. The top die 130 includes a top substrate 132, a top interconnect structure 134 over the top substrate 132, and a top bonding layer 136 disposed on the top interconnect structure 134. In the IC device package 100, the top die 130 is flipped upside down and bonded to the bottom die 120 by directly bonding the top bonding layer 136 to the bottom bonding layer 126. Each of the bottom substrate 122 and the top substrate 132 may be a bulk silicon (Si) substrate. Alternatively, each of the bottom substrate 122 and the top substrate 132 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. In some implementations, each of the bottom substrate 122 and the top substrate 132 includes one or more group III-V materials, one or more group II-VI materials, or combinations thereof. In still some instances, each of the bottom substrate 122 and the top substrate 132 is a semiconductor-on-insulator substrate, such as a silicon-on-insulator (SOI) substrate, a silicon germanium-on-insulator (SGOI) substrate, or a germanium-on-insulator (GeOI) substrate.

While not explicitly illustrated in FIG. 1 or 2, each of the bottom substrate 122 and the top substrate 132 may include active devices in the device region 102. The active devices may include planar devices or multi-gate devices. A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, GAA transistor may also be referred to as a surrounding gate transistor (SGT) or a multi-bridge-channel (MBC) transistor. In the inner seal ring region 104 and the outer seal ring region 106, each of the bottom substrate 122 and the top substrate 132 includes structures similar to the functional active devices in the device region 102 but those features in the inner seal ring regions 104 are not functional and some parts of it may be electrically floating.

Reference is still made to FIG. 2. Each of the bottom interconnect structure 124 and the top interconnect structure 134 may include 3 to 20 metal layers (or metallization layers). Each of the metal layers includes conductive lines embedded in an intermetal dielectric (IMD) layer. Each of the bottom interconnect structure 124 and the top interconnect structure 134 also includes contact vias that vertically interconnect conductive lines in different metal layers. The IMD layer may include materials such as tetraethylorthosilicate (TEOS) oxide, un-doped silicate glass, or doped silicon oxide, borophosphosilicate glass (BPSG), fused silica glass (FSG), phosphosilicate glass (PSG), boron doped silicon glass (BSG), silicon oxycarbide, and/or other suitable dielectric materials. The conductive lines and contact vias may include copper (Cu), titanium nitride (TiN), tungsten (W), or ruthenium (Ru). In one embodiment, the conductive lines and contact vias may include copper (Cu). The metal lines and contact vias of the bottom interconnect structure 124 in the device region 102 functionally interconnect the active devices fabricated on the bottom substrate 122. The metal lines and contact vias of the top interconnect structure 134 in the device region 102 functionally interconnect the active devices fabricated on the top substrate 132. In the inner seal ring region 104 and the outer seal ring region 106, the bottom interconnect structure 124 and the top interconnect structure 134 include sealing or stress buffering structures surrounding the device region 102. As will be described further below, the bottom interconnect structure 124 and the top interconnect structure 134 may include seal ring wall structures that extend completely around the device region 102 in the outer seal ring region 106. In the inner seal ring region 104, the bottom interconnect structure 124 and the top interconnect structure 134 may include via towers or via pillars that include dummy metal pads vertically linked together by contact vias. As used herein, dummy metal pads refer to metal pads that are not used to interconnect the active devices in the device region 102. Because differences of structures in the inner seal ring region 104 and the outer seal ring region 106, the inner seal ring region 104 may also be referred to as a seal ring enhancement region 104.

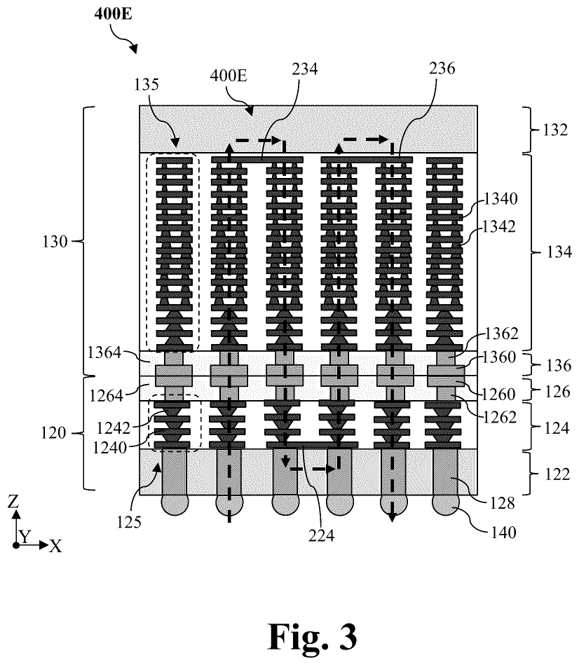

Reference is briefly made to FIG. 1. The IC device package 100 includes at least one crack sensor in the inner seal ring region 104. In some embodiments represented in FIG. 1, the IC device package 100 includes a first-type corner crack sensor 400C and a first-type edge crack sensor 400E. As shown in FIG. 1, the first-type corner crack sensor 400C is disposed adjacent a cutoff corner of the device region 102 and the first-type edge crack sensor 400E is disposed along an edge of the device region 102. Each of the first-type corner crack sensor 400C and the first-type edge crack sensor 400E may include a daisy chain structure that loops in more than one via towers in the bottom interconnect structure 124 and more than one via towers in the top interconnect structure 134. The daisy chain structure is better illustrated in FIG. 3.

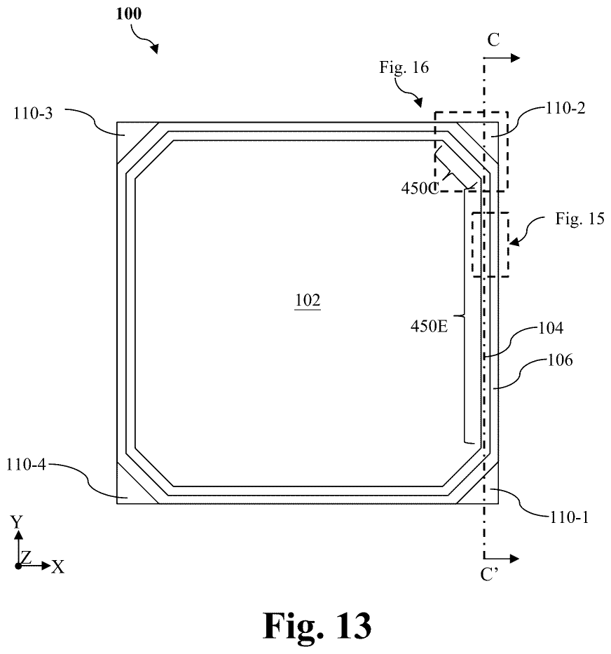

FIG. 3 illustrates an enlarged cross-sectional view of the first-type edge crack sensor 400E in the inner seal ring region 104 of the IC device package 100 along line B-B′ in FIG. 1. As illustrated in FIG. 3, in the inner seal ring region 104, the bottom interconnect structure 124 includes bottom dummy pads 1240 and bottom contact vias 1242 that are vertically connected to form a bottom via tower 125. Similarly, in the inner seal ring region 104, the top interconnect structure 134 includes top dummy pads 1340 and top contact vias 1342 that are vertically connected to form a top via tower 135. In some embodiments, the bottom dummy pads 1240, the bottom contact vias 1242, the top dummy pads 1340, and the top contact vias 1342 may include copper (Cu), titanium nitride (TiN), tungsten (W), or ruthenium (Ru). In one embodiment, they may include copper (Cu). In some embodiments, each of the bottom via towers 125 extends through a thickness of the bottom interconnect structure 124 along the Z direction and each of the top via towers 135 extends through a thickness of the top interconnect structure 134 along the Z direction. Unless a crack is developed along their lengths, the bottom via towers 125 and the top via towers 135 provide a vertical conductive structure that conduct electricity through the entire thickness of the bottom interconnect structure 124 and the top interconnect structure 134, respectively. While each of the bottom via towers 125 and the top via top via towers 135 in FIG. 13 includes different numbers of vias in different metal layers, it should be understood that any variation or uniformity of the number of vias in different metal layers are fully envisioned by the present disclosure.

As shown in FIG. 3, the bottom bonding layer 126 includes pairs of a bottom bonding pad 1260 and a bottom bonding contact 1262 disposed in a bottom dielectric layer 1264. The top bonding layer 136 includes pairs of a top bonding pad 1360 and a top bonding contact 1362 disposed in a top dielectric layer 1364. In some embodiments, the bottom bonding pad 1260, the bottom bonding contact 1262, the top bonding pad 1360, and the top bonding contact 1362 may include copper (Cu), tantalum (Ta), nickel (Ni), cobalt (Co), aluminum (Al), a combination thereof. In some implementations, the bottom dielectric layer 1264 and the top dielectric layer 1364 may include silicon oxide or silicon oxynitride. When a bottom bonding pad 1260 is aligned and bonded to a top bonding pad 1360, through the contact between the bottom bonding contact 1262 and a bottom via tower 125 and between the top bonding contact 1362 and a top via tower 135, the bottom via tower 125 may be electrically coupled to the top via tower 135 that is directly over it. In some embodiments represented in FIG. 3, the bottom substrate 122 includes a plurality of through vias 128. Each of the plurality through vias 128 extends completely through a thickness of the bottom substrate 122. Each of the plurality through vias 128 may include copper (Cu), tantalum (Ta), nickel (Ni), cobalt (Co), aluminum (Al), a combination thereof. In some embodiments represented in FIG. 3, a solder bump 140 is disposed on a bottom surface of each of the through vias 128. The solder bump 140 may include alloys of tin, lead, silver, copper, nickel, bismuth, or combinations thereof.

An example first-type edge crack sensor 400E is illustrated in FIG. 3. The first-type edge crack sensor 400E includes a daisy chain structure (shown as dotted lines) that, when no crack is present, allows an electrical signal to run between a bottom metal layer in the bottom interconnect structure 124 and a top metal layer in the top interconnect structure 134 at least once. The example daisy chain structure shown in FIG. 3 extends through the bottom interconnect structure 124, the bottom bonding layer 126, the top bonding layer 136, the top interconnect structure 134 four (4) times. This example daily chain structure also includes two through vias 128 and two solder bumps 140 as leads. In some embodiments, one lead is electrically coupled to a circuit ground voltage or a circuit positive supply voltage and the other lead is coupled to a sensing circuit to detect with the daisy chain structure has an open loop or a closed loop. As shown in FIG. 3, because the daisy chain structure passes through a bottom bonding pad 1260 and a top bonding pad 1360, the first-type edge crack sensor 400E is configured to detect non-bond or delamination between the bottom bonding pad 1260 and the top bonding pad 1360 that is directly over and vertically aligned with the bottom bonding pad 1260. Additionally, because the inner seal ring region 104 is closer to edges and corners of the IC device package 100 than the device region 102, crack sensors in the inner seal ring region 104 are in a better position to detect cracks, non-bond situations, or delamination early.

The daisy chain structure of the example first-type edge crack sensor 400E is also completed by metal lines in the bottom interconnect structure 124 and the top interconnect structure 134. In some embodiments represented in FIG. 3, the daisy chain structure of the example first-type edge crack sensor 400E is completed by a first metal line 224, a second metal line 234, and a third metal line 236. The first metal line 224 is disposed in the bottommost metal layer in the bottom interconnect structure 124. The second metal line 234 and the third metal line 236 are disposed in the topmost metal layer in the top interconnect structure 134. With respect the respectively substrates, the first metal line 224 is disposed in the metal layer closest to the bottom substrate 122 and the second metal line 234 and the third metal line 236 are disposed in the metal layer closest to the top substrate 132. This arrangement allows the daisy chain structure of the example first-type edge crack sensor 400E to detect cracks throughout the bottom interconnect structure 124, the bottom bonding layer 126, the top bonding layer 136, and the top interconnect structure 134. While the example first-type edge crack sensor 400E extends through the bottom interconnect structure 124, the bottom bonding layer 126, the top bonding layer 136, the top interconnect structure 134 four (4) times, it can be seen that the detection range can be expanded by connecting more bottom via towers 125 and top via towers 135 by more metal lines like the first metal line 224 or the second metal line 234. It should be understood that the first-type corner crack sensor 400C shown in FIG. 1 may also have daisy chain structures that extend through the bottom interconnect structure 124, the bottom bonding layer 126, the top bonding layer 136, the top interconnect structure 134 more than once.

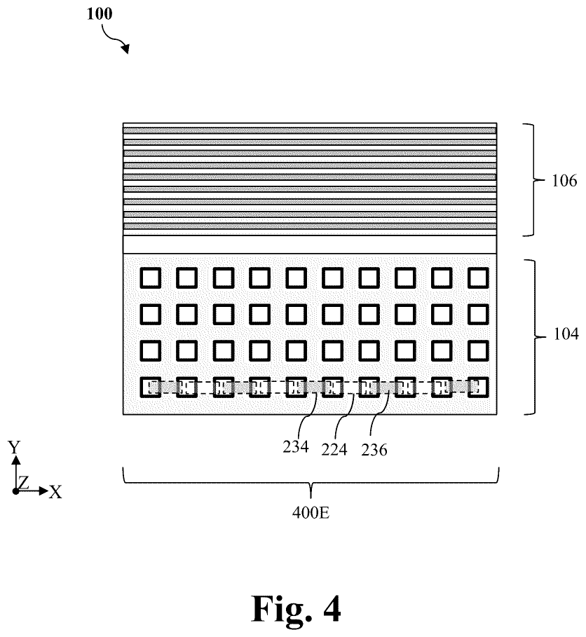

A fragmentary top view of the first-type edge crack sensor 400E in FIG. 1 is enlarged and shown in FIG. 4. In FIG. 4, the outer seal ring region 106 includes seal ring wall structures that continuously surround the device region 102. The inner seal ring region 104 includes dummy metal pads (such as the bottom dummy pad 1240 or the top dummy pad 1340 in FIG. 3) that are island-like. Combined with contact vias (such as the bottom contact via 1242 and the top contact via 1342 in FIG. 3), the dummy metal pads form via towers (such as the bottom via tower 125 and the top via tower 135 in FIG. 3) in the bottom interconnect structure 124 and the top interconnect structure 134. Combined with metal lines in the bottommost metal layer of the bottom interconnect structure 124, such as the first metal line 224 and metal lines in the topmost metal layer of the top interconnect structure 134, such as the second metal line 234 and the third metal line 236, the via towers form a daisy chain structure of the first-type edge crack sensor 400E.

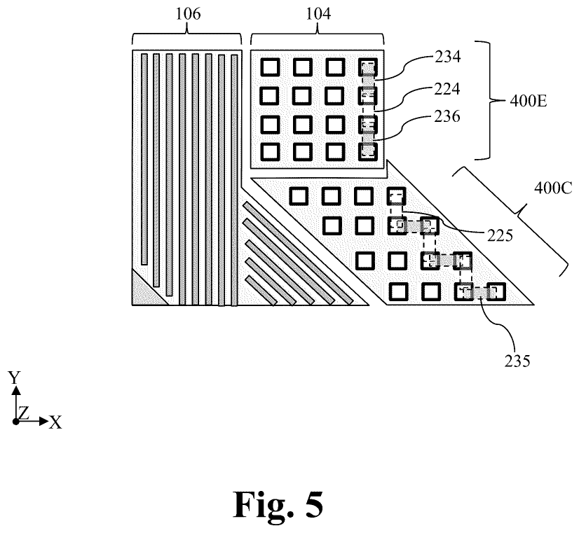

A fragmentary top view of the first-type corner crack sensor 400C in FIG. 1 is enlarged and shown in FIG. 5. Different from the first-type edge crack sensor 400E in FIG. 4, the first-type corner crack sensor 400C is adjacent a cutoff corner of the inner seal ring region 104. That is, the first-type corner crack sensor 400C is disposed in a corner portion of the inner seal ring region 104 and the corner portion extends along a direction that is at acute angle (e.g., a 45-degree angle) with an edge of the inner seal ring region 104. For this reason, the dummy metal pads in the corner portion of the inner seal ring region 104 are not arranged along a straight line along the length of the inner seal ring region 104. To accommodate this situation, the via towers in the first-type corner crack sensor 400C are connected by a fourth metal line 225 and a fifth metal line 235. In some embodiments represented in FIG. 5, the fourth metal line 225 is disposed in the bottommost metal layer in the bottom interconnect structure 124 and the fifth metal line 235 is disposed in the topmost metal layer in the top interconnect structure 134. From a top view, the via towers (such as the bottom via tower 125 and the top via tower 135 in FIG. 3), the fourth metal line 225 and the fifth metal line 235 have a stair-like shape. In the illustrated embodiment, the fourth metal line 225 extends lengthwise along the Y direction while the fifth metal line 235 extends lengthwise along the X direction substantially perpendicular to the Y direction.

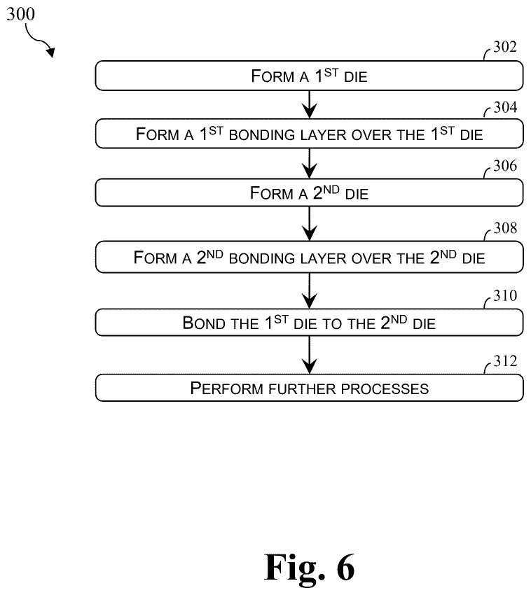

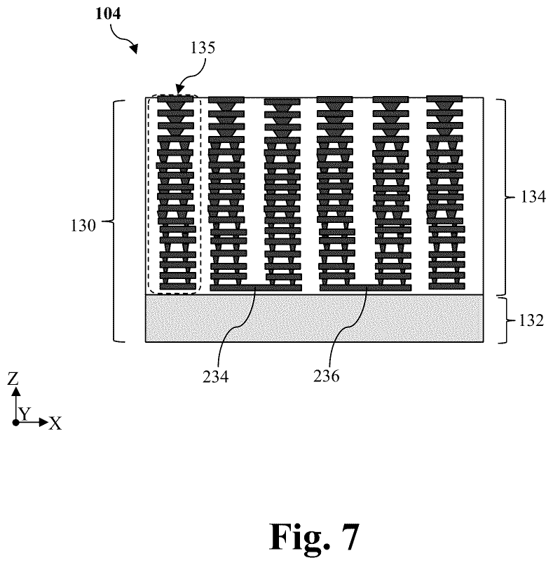

FIG. 6 is a flowchart of a method 300 for forming a crack sensor in a seal ring region of an IC device package. Methods 300 is merely an example and is not intended to limit the present disclosure to what is explicitly illustrated in method 300. Additional steps may be provided before, during and after method 300, and some steps described can be replaced, eliminated, or moved around for additional embodiments of the method 300. Not all steps are described herein in detail for reasons of simplicity. Method 300 is described below in conjunction with FIGS. 7-12, which are fragmentary cross-sectional views of an IC device package or precursors thereof at different stages of fabrication according to embodiments of method 300. Throughout the present application and across different embodiments, like reference numerals denote like features with similar structures and compositions, unless otherwise excepted.

Referring to FIGS. 6 and 7, method 300 includes a block 302 where a first die is formed. An example of the first die is the top die 130 shown in FIG. 7. The top die 130 includes a top substrate 132, a top interconnect structure 134 over the top substrate 132. The top substrate 132 may include silicon (Si). Alternatively, the top substrate 132 may include other elemental semiconductor, a compound semiconductor, III-V materials, II-VI materials, or an SOI construction. The top substrate 132 may include active regions in the device region 102 and transistor-like non-functional structures in the inner seal ring region 104. FIG. 7 only shows the inner seal ring region 104. The top interconnect structure 134 includes multiple via towers 135 that extend through a thickness of the top interconnect structure 134 along the Z direction. The top interconnect structure 134 includes the second metal line 234 and the third metal line 236 to electrically couple two adjacent top via towers 135. The second metal line 234 and the third metal line 236 are disposed in the metal layer closest to the top substrate 132.

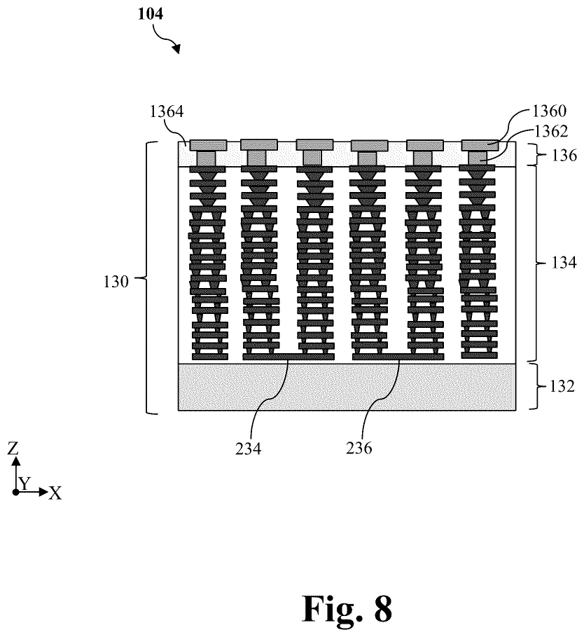

Referring to FIGS. 6 and 8, method 300 includes a block 304, where a first bonding layer is formed over the first die. An example of the first bonding layer is the top bonding layer 136 shown in FIG. 8. The top bonding layer 136 includes pairs of a top bonding pad 1360 and a top bonding contact 1362 disposed in a top dielectric layer 1364. In some embodiments, the top bonding pad 1360 and the top bonding contact 1362 may include copper (Cu), tantalum (Ta), nickel (Ni), cobalt (Co), aluminum (Al), a combination thereof. In some implementations, the top dielectric layer 1364 may include silicon oxide or silicon oxynitride.

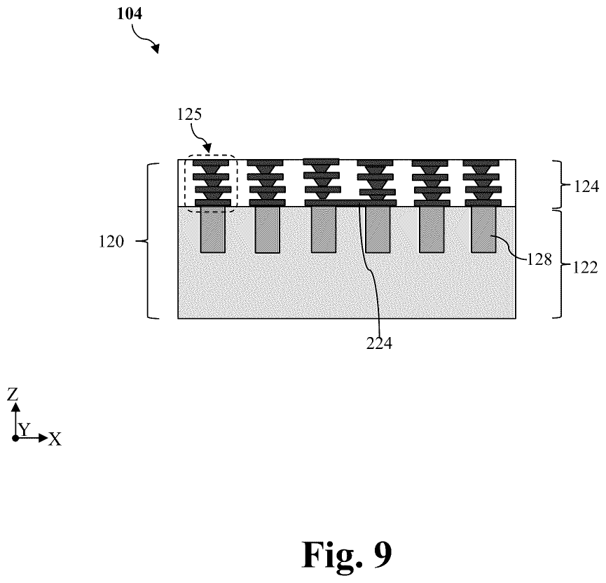

Referring to FIGS. 6 and 9, method 300 includes a block 306 where a second die is formed. An example of the second die is the bottom die 120 shown in FIG. 9. The bottom die 120 includes a bottom substrate 122, a bottom interconnect structure 124 over the bottom substrate 122. The bottom substrate 122 may include silicon (Si). Alternatively, the bottom substrate 122 may include other elemental semiconductor, a compound semiconductor, III-V materials, II-VI materials, or an SOI construction. The bottom substrate 122 may include active regions in the device region 102 and transistor-like non-functional structures in the inner seal ring region 104. FIG. 9 only shows the inner seal ring region 104. The bottom interconnect structure 124 includes multiple via towers 125 that extend through a thickness of the bottom interconnect structure 124 along the Z direction. In some embodiments illustrated in FIG. 9, the bottom substrate 122 includes a plurality of through vias 128. Each of the plurality through vias 128 extends completely through a thickness of the bottom substrate 122. Each of the plurality through vias 128 may include copper (Cu), tantalum (Ta), nickel (Ni), cobalt (Co), aluminum (Al), a combination thereof. The bottom interconnect structure 124 includes the first metal line 224 to electrically couple two adjacent bottom via towers 125. The first metal line 224 is disposed in the metal layer closest to the bottom substrate 122.

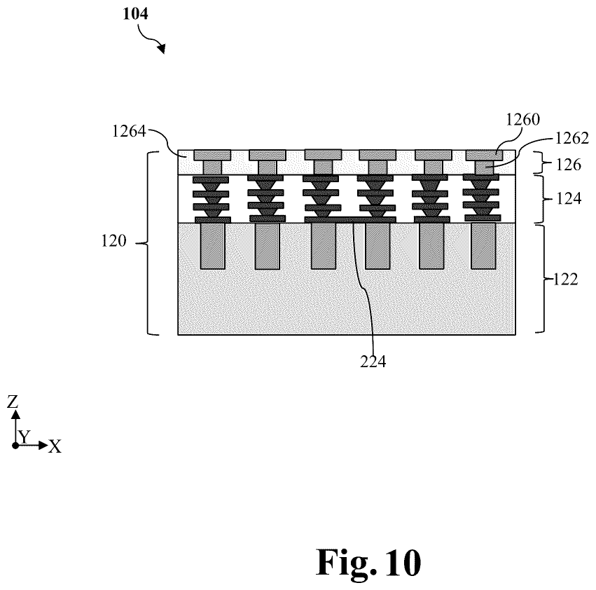

Referring to FIGS. 6 and 10, method 300 includes a block 308 where a second bonding layer is formed over the second die. An example of the second bonding layer is the bottom bonding layer 126 shown in FIG. 10. The bottom bonding layer 126 includes pairs of a bottom bonding pad 1260 and a bottom bonding contact 1262 disposed in a bottom dielectric layer 1264. In some embodiments, the bottom bonding pad 1260 and the bottom bonding contact 1262 may include copper (Cu), tantalum (Ta), nickel (Ni), cobalt (Co), aluminum (Al), a combination thereof. In some implementations, the bottom dielectric layer 1264 may include silicon oxide or silicon oxynitride.

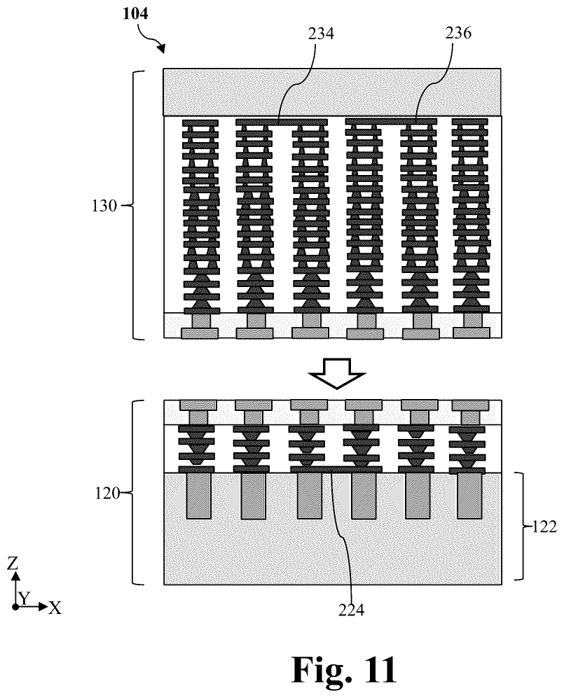

Referring to FIGS. 6 and 11, method 300 includes a block 310 where the first die is bonded to the second die. In an example process to bond the top die 130 to the bottom die 120, the bottom bonding layer 126 and the top bonding layer 136 are planarized by, for example, a chemical mechanical polishing (CMP) process. Then, surfaces of the bottom bonding layer 126 and the top bonding layer 136 are cleaned to remove organic and metallic contaminants. For example, a sulfuric acid hydrogen peroxide mixture (SPM), a mixture of ammonium hydroxide and hydrogen peroxide (SC1), or both may be used to remove organic contaminants on surfaces of the bottom bonding layer 126 and the top bonding layer 136. A mixture of hydrochloric acid and hydrogen peroxide (SC2) may be used to remove metallic contaminants. Besides cleaning, the planarized surfaces of the bottom bonding pad 1260, the top bonding pad 1360, the bottom dielectric layer 1264, and the top dielectric layer 1364 may be treated by an argon plasma or a nitrogen plasma to activate the surfaces thereof. After the top bonding pads 1360 are aligned with the bottom bonding pads 1260, an anneal is performed to promote the van der Waals force bonding of the bottom dielectric layer 1264 and the top dielectric layer 1364 as well as the surface-activated bonding (SAB) of the top bonding pads 1360 and the bottom bonding pads 1260. In some instances, the anneal includes a temperature between about 200° C. and about 300° C.

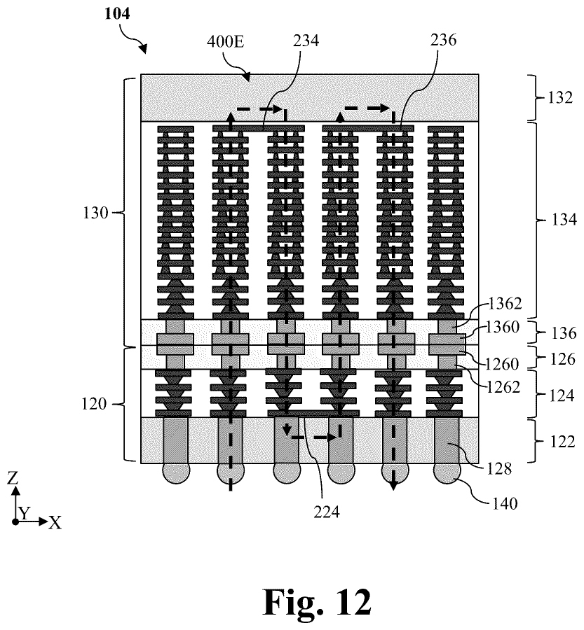

Referring to FIGS. 6 and 12, method 300 includes a block 312 where further processes are performed. Such further processes may include thinning of the bottom substrate 122 to expose the through vias 128. The thinning may include grinding, polishing, or a combination thereof. After the through vias 128 are exposed, solder bumps 140 are formed on bottom surfaces of each of the through vias 128. The solder bump 140 may include alloys of tin, lead, silver, copper, nickel, bismuth, or combinations thereof. Upon conclusion of operations at block 312, the example first-type edge crack sensor 400E is substantially formed.

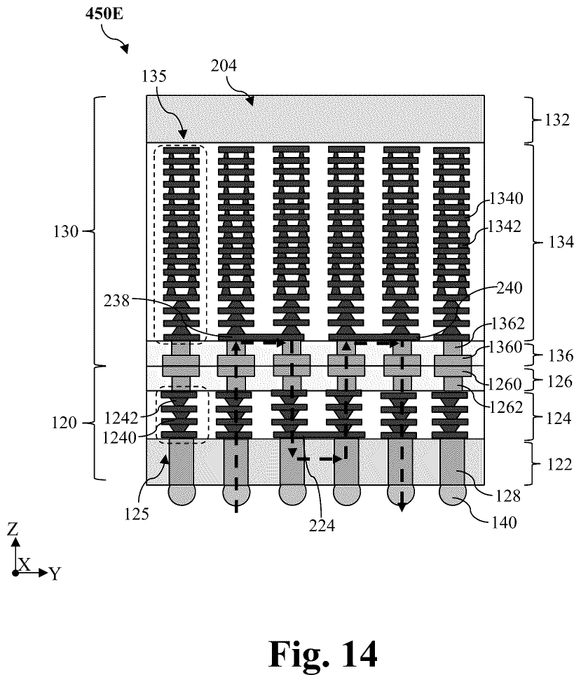

FIG. 13 illustrates a top view of an IC device package 100 similar to the IC device package 100 shown in FIG. 1. The IC device package 100 includes a device region 102, an inner seal ring region 104 continuously surrounding the device region 102, and an outer seal ring region 106 continuously surrounding the inner seal ring region 104. In some embodiments, each of the device region 102, the inner seal ring region 104, and the outer seal ring region 106 includes four cutoff corners to have an octagonal shape from a top view. As illustrated in FIG. 1, four corner areas 110-1, 110-2, 110-3, and 110-4 fill the four cutoff corners such that the IC device package 100 has a square shape or a rectangular shape from a top view. In one embodiment, the IC device package 100 includes a square shape in a top view. In some implementations, each of the four corner areas 110-1, 110-2, 110-3, and 110-4 resembles an isosceles right triangle. Instead of having first-type crack sensors 400E and 400C, the IC device package 100 in FIG. 13 is equipped with second-type crack sensors, including a second-type edge crack sensor 450E and a second-type corner crack sensor 450C. As shown in FIG. 13, the second-type corner crack sensor 450C is disposed adjacent a cutoff corner of the device region 102 and the second-type edge crack sensor 450E is disposed along an edge of the device region 102. Each of the second-type corner crack sensor 450C and the second-type edge crack sensor 450E may include a daisy chain structure that loops in more than one via towers in the bottom interconnect structure 124 but does not loop in any via towers in the top interconnect structure 134. The daisy chain structure is better illustrated in FIG. 14.

FIG. 14 illustrates an enlarged cross-sectional view of the second-type edge crack sensor 450E in the inner seal ring region 104 of the IC device package 100 along line C-C′ in FIG. 13. As illustrated in FIG. 14, in the inner seal ring region 104, the bottom interconnect structure 124 includes bottom dummy pads 1240 and bottom contact vias 1242 that are vertically connected to form a bottom via tower 125. Similarly, in the inner seal ring region 104, the top interconnect structure 134 includes top dummy pads 1340 and top contact vias 1342 that are vertically connected to form a top via tower 135. In some embodiments, the bottom dummy pads 1240, the bottom contact vias 1242, the top dummy pads 1340, and the top contact vias 1342 may include copper (Cu), titanium nitride (TiN), tungsten (W), or ruthenium (Ru). In one embodiment, they may include copper (Cu). In some embodiments, each of the bottom via towers 125 extends through a thickness of the bottom interconnect structure 124 along the Z direction and each of the top via towers 135 extends through a thickness of the top interconnect structure 134 along the Z direction. Unless a crack is developed along their lengths, the bottom via towers 125 and the top via towers 135 provide a vertical conductive structure that conduct electricity through the entire thickness of the bottom interconnect structure 124 and the top interconnect structure 134, respectively.

As shown in FIG. 14, the bottom bonding layer 126 includes pairs of a bottom bonding pad 1260 and a bottom bonding contact 1262 disposed in a bottom dielectric layer 1264. The top bonding layer 136 includes pairs of a top bonding pad 1360 and a top bonding contact 1362 disposed in a top dielectric layer 1364. In some embodiments, the bottom bonding pad 1260, the bottom bonding contact 1262, the top bonding pad 1360, and the top bonding contact 1362 may include copper (Cu), tantalum (Ta), nickel (Ni), cobalt (Co), aluminum (Al), a combination thereof. In some implementations, the bottom dielectric layer 1264 and the top dielectric layer 1364 may include silicon oxide or silicon oxynitride. When a bottom bonding pad 1260 is aligned and bonded to a top bonding pad 1360, through the contact between the bottom bonding contact 1262 and a bottom via tower 125 and between the top bonding contact 1362 and a top via tower 135, the bottom via tower 125 may be electrically coupled to the top via tower 135 that is directly over it. In some embodiments represented in FIG. 3, the bottom substrate 122 includes a plurality of through vias 128. Each of the plurality through vias 128 extends completely through a thickness of the bottom substrate 122. Each of the plurality through vias 128 may include copper (Cu), tantalum (Ta), nickel (Ni), cobalt (Co), aluminum (Al), a combination thereof. In some embodiments represented in FIG. 14, a solder bump 140 is disposed on a bottom surface of each of the through vias 128. The solder bump 140 may include alloys of tin, lead, silver, copper, nickel, bismuth, or combinations thereof.

An example second-type edge crack sensor 450E is illustrated in FIG. 14. The second-type edge crack sensor 450E includes a daisy chain structure (shown as dotted lines) that, when no crack is present, allows an electrical signal to run between a bottom metal layer in the bottom interconnect structure 124 and a bottom metal layer in the top interconnect structure 134 at least once. Here, the bottom metal layer refers to the metal layer in the top interconnect structure 134 that is farther away from the top substrate 132. The example daisy chain structure shown in FIG. 14 extends through the bottom interconnect structure 124, the bottom bonding layer 126 and the top bonding layer 136 four (4) times. Reference is now made to FIGS. 14 and 3. Different from the daisy chain structure of the example first-type edge crack sensor 400E shown in FIG. 3, the daisy chain structure of the example second-type edge crack sensor 450E in FIG. 14 do not go through an entire height of any of the top via towers 135. This means that the second-type edge crack sensor 450E is not configured to detect any delamination or crack in any of the top via towers 135. It can also be understood that the operation of second-type edge crack sensor 450E in FIG. 14 does not depend on the presence or integrity of the top via towers 135. In some alternative embodiments not shown in figures, the top via towers 135 may be omitted when only the second-type edge crack sensor 450E is deployed. This daily chain structure of the example second-type edge crack sensor 450E also includes two through vias 128 and two solder bumps 140 as leads. In some embodiments, one lead is electrically coupled to a circuit ground voltage or a circuit positive supply voltage and the other lead is coupled to a sensing circuit to detect with the daisy chain structure has an open loop or a closed loop.

As shown in FIG. 14, because the daisy chain structure passes through a bottom bonding pad 1260 and a top bonding pad 1360, the second-type edge crack sensor 450E is configured to detect non-bond or delamination between the bottom bonding pad 1260 and the top bonding pad 1360 that is directly over and vertically aligned with the bottom bonding pad 1260. Additionally, because the inner seal ring region 104 is closer to edges and corners of the IC device package 100 than the device region 102, crack sensors in the inner seal ring region 104 are in a better position to detect cracks, non-bond situations, or delamination early.

The daisy chain structure of the example second-type edge crack sensor 450E is also completed by metal lines in the bottom interconnect structure 124 and the top interconnect structure 134. In some embodiments represented in FIG. 14, the daisy chain structure of the example second-type edge crack sensor 450E is completed by a first metal line 224, a sixth metal line 238, and a seventh metal line 240. The first metal line 224 is disposed in the bottommost metal layer in the bottom interconnect structure 124. The sixth metal line 238 and the seventh metal line 240 are disposed in the bottommost metal layer in the top interconnect structure 134. With respect the respectively substrates, the first metal line 224 is disposed in the metal layer closest to the bottom substrate 122 and the sixth metal line 238 and the seventh metal line 240 are disposed in the metal layer closest to the top bonding layer 136. In some embodiments represented in FIG. 14, each of the sixth metal line 238 and the seventh metal line 240 is physically and electrically coupled to two top bonding contacts 1362. This arrangement allows the daisy chain structure of the example second-type edge crack sensor 450E to detect cracks throughout the bottom interconnect structure 124, the bottom bonding layer 126, and the top bonding layer 136. While the example second-type edge crack sensor 450E extends through the bottom interconnect structure 124, the bottom bonding layer 126 and the top bonding layer 136 four (4) times, it can be seen that the detection range can be expanded by connecting more bottom via towers 125 and more top bonding contacts 1362 by more metal lines like the first metal line 224, the sixth metal line 238, or the seventh metal line 240. It should be understood that the second-type corner crack sensor 450C shown in FIG. 13 may also have daisy chain structures that extend through the bottom interconnect structure 124, the bottom bonding layer 126, and the top bonding layer 136 more than once.

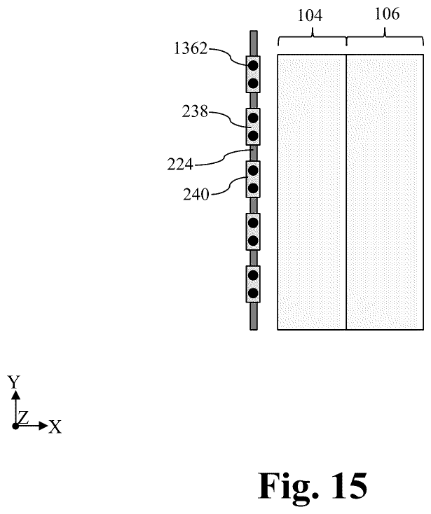

A fragmentary top view of the second-type edge crack sensor 450E in FIG. 13 is enlarged and shown in FIG. 15. In FIG. 15, the outer seal ring region 106 includes seal ring wall structures that continuously surround the device region 102. The inner seal ring region 104 includes dummy metal pads (such as the bottom dummy pad 1240 or the top dummy pad 1340 in FIG. 14) that are island-like. Combined with contact vias (such as the bottom contact via 1242 and the top contact via 1342 in FIG. 14), the dummy metal pads form via towers (such as the bottom via tower 125 and the top via tower 135 in FIG. 14) in the bottom interconnect structure 124 and the top interconnect structure 134. Combined with metal lines in the bottommost metal layer of the bottom interconnect structure 124, such as the first metal line 224 and metal lines in the bottommost metal layer of the top interconnect structure 134, such as the sixth metal line 238 and the seventh metal line 240, the bottom via towers 125, bonding contacts and bonding pads in the bottom bonding layer 126 and the top bonding layer 136 form a daisy chain structure of the second-type edge crack sensor 450E.

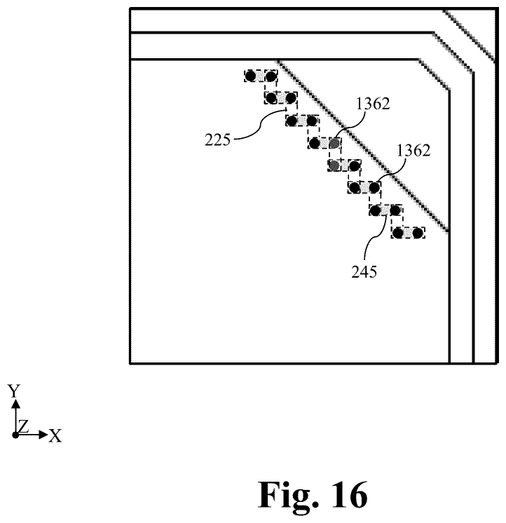

A fragmentary top view of the second-type corner crack sensor 450C in FIG. 13 is enlarged and shown in FIG. 16. Different from the second-type edge crack sensor 450E in FIG. 15, the second-type corner crack sensor 450C is adjacent a cutoff corner of the inner seal ring region 104. That is, the second-type corner crack sensor 450C is disposed in a corner portion of the inner seal ring region 104 and the corner portion extends along a direction that is at acute angle (e.g., a 45-degree angle) with an edge of the inner seal ring region 104. Because the bottommost metal layer of the top interconnect structure 134 are away from the active devices and can be quite large, it is possible to form local metal lines in the bottommost metal layer. For this reason, the dummy metal pads in the corner portion of the of the inner seal ring region 104 are not arranged along a straight line along the length of the inner seal ring region 104. To accommodate this situation, the bottom via towers and top bonding contacts 1362 in the second-type corner crack sensor 450C are connected by a fourth metal line 225 and a eighth metal line 245. In some embodiments represented in FIG. 16, the fourth metal line 225 is disposed in the bottommost metal layer in the bottom interconnect structure 124 and the eighth metal line 245 is disposed in the bottommost metal layer in the top interconnect structure 134. From a top view, the top bonding contacts 1362, the fourth metal line 225 and the eighth metal line 245 have a stair-like shape. In the illustrated embodiment, the fourth metal line 225 extends lengthwise along the Y direction while the eighth metal line 245 extends lengthwise along the X direction perpendicular to the Y direction.

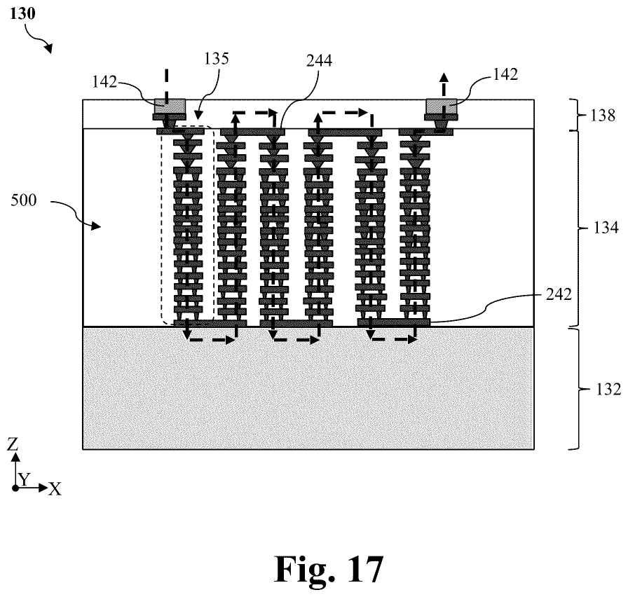

FIGS. 17, 18 and 19 illustrate a third-type crack sensor 500 that allows chip-level, package-level, and system level crack detection. Reference is first made to FIG. 17, which illustrates a top die 130 as an example of an IC die. The top die 130 includes a top substrate 132, a top interconnect structure 134 disposed on the top substrate 132, and a redistribution layer (RDL) 138 over the top interconnect structure 134. As described above and illustrated in FIGS. 1 and 2, the top die 130 includes a device region 102, an inner seal ring region 104 continuously surrounding the device region 102, and an outer seal ring region 106 continuously surrounding the inner seal ring region 104. The top die 130 includes a third-type crack sensor 500 disposed in the inner seal ring region 104. It is noted that the third-type crack sensor 500 in FIG. 17 spans across a width of the top die 130 because the cross section shown in FIG. 17 cuts through the inner seal ring region 104 of the top die 130. In the embodiments illustrated in FIG. 17, the top die 130 is not bonded to another die, rather it is coupled to the RDL 138 and packaged on its own.

Referring still to FIG. 17, the third-type crack sensor 500 includes a daisy chain structure (shown as dotted lines) that, when no crack is present, allows an electrical signal to run between an input/output (I/O) pad 142, more than one top via tower 135, metal lines connecting the more than one top via tower, and another I/O pad 142. In some instances, the I/O pads 142 may include aluminum (Al), copper (Cu), or an alloy thereof and may be referred to as an aluminum pad. In the depicted embodiment, the daisy chain structure of the third-type crack sensor 500 also routes through more than one bottom metal line 242 and more than one top metal line 244. Although not explicitly shown in the figures, the third-type crack sensor 500 may also include third-type edge crack sensors and third-type corner crack sensors. The third-type edge crack sensors may be disposed along an edge of the top die 130 and the third-type corner crack sensors may be disposed adjacent a cutoff corner of the inner seal ring region 104. The example daisy chain structure shown in FIG. 17 extends through the top interconnect structure 134 six (6) times. It should be understood that the daisy chain structure of the third-type crack sensor 500 may be more expansive to include more top via towers 135 or less expansive to include less top via towers 135. At a chip level, any crack or non-bond in the top via towers 135 may be detected by checking an electrical continuity in the daisy chain. In an example, probes may come in contact with the I/O pads 142 to probe the third-type crack sensor 500.

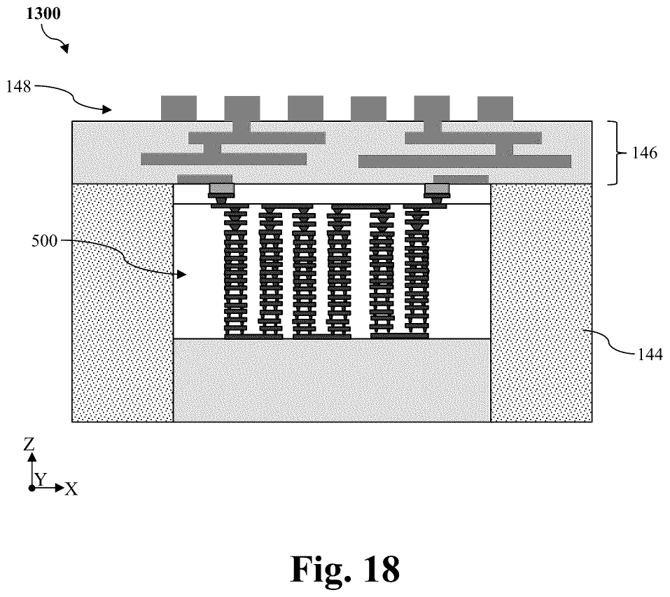

The top die 130 shown in FIG. 17 may go through further packaging steps to form a package 1300 shown in FIG. 18. The package 1300 includes a molding material 144 surrounding the top die 130 and a package redistribution layer (RDL) 146 over the top die 130 and the molding material 144. For bonding to further structures or for testing purposes, the package 1300 also includes connection features 146. In some embodiments, the connection features 146 may include contact pads, controlled collapse chip connection (C4) bumps or micro-bumps. In some implementations, because the I/O pads 142 connecting to the daisy chain structure of the third-type crack sensor 500 are electrically coupled to some of the connection features 148, any crack or non-bond in the top via towers 135 may be detected, at the package level, by checking an electrical continuity in the daisy chain by probing the connection features 148.

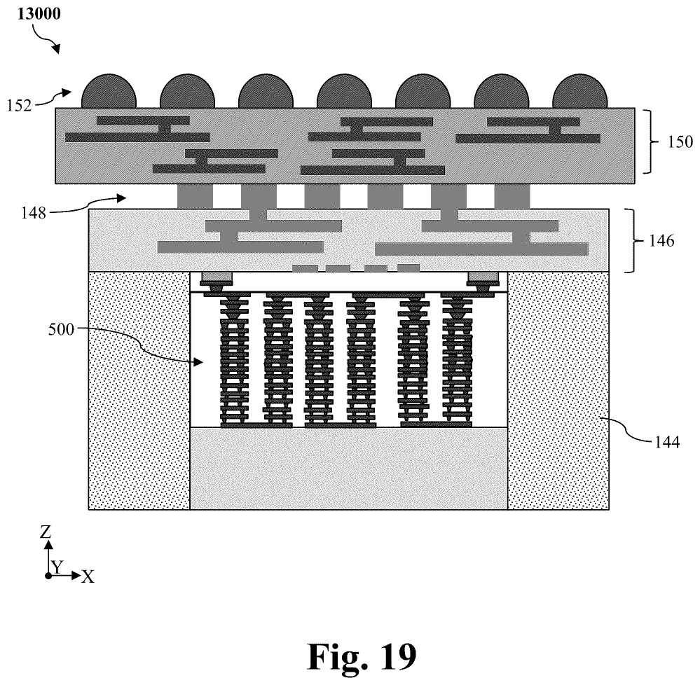

The package 1300 shown in FIG. 18 may go through further process steps to form a system 13000 shown in FIG. 19. The system 13000 includes a printed circuit board (PCB) 150 and the package 1300 electrically coupled to the PCB 150 by way of the connection features 148. For mounting of the system 13000, ball grid array solder balls 152 are formed on the PCB 150. In some implementations, because the I/O pads 142 connecting to the daisy chain structure of the third-type crack sensor 500 are electrically coupled to some of the solder balls 152, any crack or non-bond in the top via towers 135 may be detected, at the system level, by checking an electrical continuity in the daisy chain by probing the solder balls 152.

In one exemplary aspect, the present disclosure is directed to a semiconductor structure. The semiconductor structure includes a first substrate including a device region and a ring region surrounding the device region, a first interconnect structure over the first substrate, the first interconnect structure including a first via tower and a second via tower extending through the first interconnect structure and disposed directly over the ring region, a first bonding layer over the first interconnect structure and including a first metal bonding feature, a second bonding layer over the first bonding layer and including a second metal bonding feature in contact with the first metal bonding feature, and a second interconnect structure over the second bonding layer, the second interconnect structure including a third via tower extending through the second interconnect structure and disposed directly over the ring region. The first via tower is electrically coupled to the second via tower by way of a first metal line in the first interconnect structure. The first via tower is electrically coupled to the third via tower by way of the first metal bonding feature and the second metal bonding feature.

In some embodiments, the first metal line is adjacent the first substrate and away from the first bonding layer. In some embodiments, the semiconductor structure further includes a second substrate disposed over the second interconnect structure. In some embodiments, the second interconnect structure further includes a fourth via tower extending through the second interconnect structure. In some embodiments, the third via tower is electrically coupled to the fourth via tower by way of a second metal line in the second interconnect structure. In some embodiments, the second metal line is adjacent the second substrate and away from the second bonding layer. In some implementations, the fourth via tower is electrically coupled to the second via tower by way of the second metal line, the third via tower, the first via tower, and the first metal line. In some instances, the first interconnect structure further includes a fifth via tower, the first bonding layer further includes a third metal bonding feature, the second bonding layer further includes a fourth metal bonding feature in contact with the third metal bonding feature, and the fifth via tower is electrically coupled to the fourth via tower by way of the third metal bonding feature and the fourth metal bonding feature. In some embodiments, the first substrate includes a through via vertically extending through the first substrate and the through via is electrically coupled to the fifth via tower.

In another exemplary aspect, the present disclosure is directed to a device structure. The device structure includes a first die including a first device region and a first seal ring region surrounding the first device region, a first bonding layer disposed over the first die, a second bonding layer disposed over the first bonding layer, a second die disposed over the second bonding layer and including a second device region and a second seal ring region surrounding the second device region, and a crack sensor disposed in the first seal ring region, the first bonding layer, the second bonding layer, and the second sealing region.

In some embodiments, the second seal ring region vertically overlaps with the first seal ring region. In some embodiments, the first die includes a first semiconductor substrate, and a first interconnect structure over the first semiconductor substrate and the second die includes a second interconnect structure disposed over the second bonding layer, and a second semiconductor substrate disposed over the second interconnect structure. In some implementations, the first interconnect structure includes a first plurality of via towers extending through an entire thickness of the first interconnect structure, the second interconnect structure includes a second plurality of via towers extending through an entire thickness of the second interconnect structure, and the crack sensor includes a daisy chain structure that includes more than one of the first plurality of via towers and more than one of the second plurality of via towers. IN some embodiments, the first plurality of via towers are disposed in the first seal ring region and the second plurality of via towers are disposed in the second seal ring region. In some embodiments, the first bonding layer includes a first plurality of bonding features, the second bonding layer includes a second plurality of bonding features, and each of the first plurality of bonding features is vertically aligned and in contact with one of the second plurality of bonding features. In some embodiments, the daisy chain structure further includes more than one of the first plurality of bonding features and more than one of the second plurality of bonding features.

In yet another exemplary aspect, the present disclosure is directed to a method. The method includes forming a first die that includes a first semiconductor substrate, and a first interconnect structure over the first semiconductor substrate, forming a first bonding layer over the first interconnect structure, forming a second die that includes a second semiconductor substrate, and a second interconnect structure over the second semiconductor substrate, forming a second bonding layer over the second interconnect structure, and bonding the second die to the first die by bonding the second bonding layer to the first bonding layer. The first interconnect structure includes a first device region and a first seal ring region surrounding the first device region. The second interconnect structure includes a second device region and a second seal ring region surrounding the second device region. After the bonding, the first seal ring region is vertically aligned with the second seal ring region. The first interconnect structure includes a first via tower and a second via tower in the first seal ring region. The first via tower and the second via tower are connected by a first metal line in the first interconnect structure. The second interconnect structure includes a third via tower and a fourth via tower in the second seal ring region. The third via tower and the fourth via tower are connected by a second metal line in the second interconnect structure.

In some embodiments, but for the first metal line, the first via tower and the second via tower are electrically isolated from each other and but for the second metal line, the third via tower and the fourth via tower are electrically isolated from each other. In some embodiments, the first metal line is adjacent the first semiconductor substrate and away from the first bonding layer and the second metal line is adjacent the second semiconductor substrate and away from the second bonding layer. In some embodiments, the first metal line is adjacent the first bonding layer and away from the first semiconductor substrate and the second metal line is adjacent the second semiconductor substrate and away from the second bonding layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first substrate comprising a device region and a ring region surrounding the device region;
a first interconnect structure over the first substrate, the first interconnect structure comprising a first via tower and a second via tower extending through the first interconnect structure and disposed directly over the ring region;
a first bonding layer over the first interconnect structure and comprising a first metal bonding feature;
a second bonding layer over the first bonding layer and comprising a second metal bonding feature in contact with the first metal bonding feature; and
a second interconnect structure over the second bonding layer, the second interconnect structure comprising a third via tower extending through the second interconnect structure and disposed directly over the ring region,
wherein the first via tower is electrically coupled to the second via tower by way of a first metal line in the first interconnect structure,
wherein the first via tower is electrically coupled to the third via tower by way of the first metal bonding feature and the second metal bonding feature.

2. The semiconductor structure of claim 1, wherein the first metal line is adjacent the first substrate and away from the first bonding layer.

3. The semiconductor structure of claim 1, further comprising:
a second substrate disposed over the second interconnect structure.

4. The semiconductor structure of claim 3, wherein the second interconnect structure further comprises a fourth via tower extending through the second interconnect structure.

5. The semiconductor structure of claim 4, wherein the third via tower is electrically coupled to the fourth via tower by way of a second metal line in the second interconnect structure.

6. The semiconductor structure of claim 5, wherein the second metal line is adjacent the second substrate and away from the second bonding layer.

7. The semiconductor structure of claim 5, wherein the fourth via tower is electrically coupled to the second via tower by way of the second metal line, the third via tower, the first via tower, and the first metal line.

8. The semiconductor structure of claim 5,
wherein the first interconnect structure further comprise a fifth via tower,
wherein the first bonding layer further comprises a third metal bonding feature,
wherein the second bonding layer further comprises a fourth metal bonding feature in contact with the third metal bonding feature,
wherein the fifth via tower is electrically coupled to the fourth via tower by way of the third metal bonding feature and the fourth metal bonding feature.

9. The semiconductor structure of claim 8,
wherein the first substrate comprises a through via vertically extending through the first substrate,
wherein the through via is electrically coupled to the fifth via tower.

10. A device structure, comprising:
a first die comprising a first device region and a first seal ring region surrounding the first device region;
a first bonding layer disposed over the first die;
a second bonding layer disposed over the first bonding layer;
a second die disposed over the second bonding layer and comprising a second device region and a second seal ring region surrounding the second device region; and
a crack sensor disposed in the first seal ring region, the first bonding layer, the second bonding layer, and the second sealing region.

11. The device structure of claim 10, wherein the second seal ring region vertically overlaps with the first seal ring region.

12. The device structure of claim 10,
wherein the first die comprises:
a first semiconductor substrate, and
a first interconnect structure over the first semiconductor substrate,
wherein the second die comprises:
a second interconnect structure disposed over the second bonding layer, and
a second semiconductor substrate disposed over the second interconnect structure.

13. The device structure of claim 12,
wherein the first interconnect structure comprises a first plurality of via towers extending through an entire thickness of the first interconnect structure,
wherein the second interconnect structure comprises a second plurality of via towers extending through an entire thickness of the second interconnect structure,
wherein the crack sensor comprises a daisy chain structure that includes more than one of the first plurality of via towers and more than one of the second plurality of via towers.

14. The device structure of claim 13,
wherein the first plurality of via towers are disposed in the first seal ring region,
wherein the second plurality of via towers are disposed in the second seal ring region.

15. The device structure of claim 13,
wherein the first bonding layer comprises a first plurality of bonding features,
wherein the second bonding layer comprises a second plurality of bonding features,
wherein each of the first plurality of bonding features is vertically aligned and in contact with one of the second plurality of bonding features.

16. The device structure of claim 15, wherein the daisy chain structure further includes more than one of the first plurality of bonding features and more than one of the second plurality of bonding features.

17. A method, comprising:
forming a first die that comprises:
a first semiconductor substrate, and
a first interconnect structure over the first semiconductor substrate;
forming a first bonding layer over the first interconnect structure;
forming a second die that comprises:
a second semiconductor substrate, and
a second interconnect structure over the second semiconductor substrate;
forming a second bonding layer over the second interconnect structure; and
bonding the second die to the first die by bonding the second bonding layer to the first bonding layer,
wherein the first interconnect structure comprises a first device region and a first seal ring region surrounding the first device region,
wherein the second interconnect structure comprises a second device region and a second seal ring region surrounding the second device region,
wherein, after the bonding, the first seal ring region is vertically aligned with the second seal ring region,
wherein the first interconnect structure comprises a first via tower and a second via tower in the first seal ring region,
wherein the first via tower and the second via tower are connected by a first metal line in the first interconnect structure,
wherein the second interconnect structure comprises a third via tower and a fourth via tower in the second seal ring region,
wherein the third via tower and the fourth via tower are connected by a second metal line in the second interconnect structure.

18. The method of claim 17,
Wherein, but for the first metal line, the first via tower and the second via tower are electrically isolated from each other,
wherein, but for the second metal line, the third via tower and the fourth via tower are electrically isolated from each other.

19. The method of claim 17,
wherein the first metal line is adjacent the first semiconductor substrate and away from the first bonding layer,
wherein the second metal line is adjacent the second semiconductor substrate and away from the second bonding layer.

20. The method of claim 17,
wherein the first metal line is adjacent the first bonding layer and away from the first semiconductor substrate,
wherein the second metal line is adjacent the second semiconductor substrate and away from the second bonding layer.
